(19) United States
(12) Patent Application Publication
(10) Pub. No.: US 2024/0116467 A1
(43) Pub. Date: Apr. 11, 2024

(54) ELECTRICAL CONNECTION BOX

(71) Applicant: Sumitomo Wiring Systems, Ltd., Yokkaichi-shi, Mie (JP)

(72) Inventor: Masanao KURITA, Yokkaichi-shi, Mie (JP)

(21) Appl. No.: 18/263,828

(22) PCT Filed: Jan. 13, 2022
(86) PCT No.: PCT/JP2022/000823

§ 371 Date: Aug. 1, 2023

(30) Foreign Application Priority Data
Feb. 2, 2021 (JP) 2021-014701

(51) Int. Cl. B60R 16/023; B60R 16/02; H01B 7/00; H01B 13/012

(52) U.S. Cl. CPC B60R 16/0239; B60R 16/0215; H01B 7/0045; H01B 13/01263

(57) ABSTRACT

An electrical connection box including a case, a relay attached to the case in a state exposed outside the case, and a wire harness that is to be connected to a sensor that measures a state of the relay, and is provided outside of the case. The wire harness includes a lead to be electrically connected to the sensor, and a guide member that is provided along the lead so as to guide the extending direction of the lead.

### CROSS-REFERENCE TO RELATED APPLICATIONS

This application is the U.S. national stage of PCT/JP2022/000823 filed on Jan. 13, 2022, which claims priority of Japanese Patent Application No. JP 2021-014701 filed on Feb. 2, 2021, the contents of which are incorporated herein.

### TECHNICAL FIELD

The present disclosure relates to an electrical connection box.

### BACKGROUND

In automobiles, for example, in order to supply power from a battery to each of a plurality of in-vehicle devices, electrical wires from the battery are first connected to an electrical connection box (also referred to as a “junction box”), and electrical wires are also respectively connected between the electrical connection box and the in-vehicle devices. The electrical connection box includes a case for accommodating relays (relay boxes). Such an electrical connection box is disclosed in JP 2016-25736A.

There are cases where a sensor is attached to a relay in order to measure a relay state (e.g., temperature). In this case, a lead is provided in order to extract a detection signal from the sensor to an external device. The relay is provided in a state exposed outside a case, and the lead is routed outside the case. The lead is relatively soft and easily bent. Therefore, when the case is jolted due to vibration caused by traveling of a vehicle, for example, there is a risk that the lead will be damaged by scraping against parts (e.g., bus bar) outside the case.

Therefore, the present disclosure aims to provide an electrical connection box that can reduce the risk of damage to leads.

### SUMMARY

An electrical connection box of the present disclosure is an electrical connection box including a case, a relay attached to the case in a state exposed outside the case, and a wire harness that is connected to a sensor that measures the state of the relay, and is provided outside of the case, wherein the wire harness includes a lead to be electrically connected to the sensor, and a guide member that is provided along the lead so as to guide the extending direction of the lead.

### Advantageous Effects

According to the present disclosure, the risk of damage to leads can be reduced.

### BRIEF DESCRIPTION OF DRAWINGS

FIG. 1 is a perspective view of an electrical connection box according to the present embodiment.

FIG. 2 is a plan view of the electrical connection box according to the present embodiment.

FIG. 3 is an enlarged view of a bus bar and a connection portion in FIG. 1.

FIG. 4 is an enlarged view of the bus bar and the connection portion viewed from the front.

FIG. 5 is a schematic diagram for describing a wire harness according to the present embodiment.

FIG. 6 is a schematic diagram for describing a wire harness according to a modification.

FIG. 7 is a perspective view for describing a second guide member according to a modification.

### DETAILED DESCRIPTION OF PREFERRED EMBODIMENTS

The embodiments of the present disclosure at least includes the following items as the gist.

An electrical connection box according to the present disclosure is an electrical connection box including a case, a relay attached to the case in a state exposed outside the case, and a wire harness that is connected to a sensor that measures the state of the relay, and is provided outside of the case, wherein the wire harness includes a lead to be electrically connected to the sensor, and a guide member that is provided along the lead so as to guide the extending direction of the lead.

As a result of the extending direction of the lead being guided by the guide member, the risk of the lead being damaged by scraping against parts outside the case can be reduced.

Preferably, the guide member is a wire whose rigidity in a bending direction is larger than the lead.

Preferably, the guide member is a resin bar formed so as to extend in a guiding direction of the lead.

Preferably, the wire harness further includes a resin tube that houses the lead and the guide member. With this configuration, the lead can be guided via the tube, and the configuration of the electrical connection box can be simplified.

Hereinafter, details of an embodiment of the present disclosure will be described with reference to the drawings.

### Overall Configuration of Electrical Connection Box

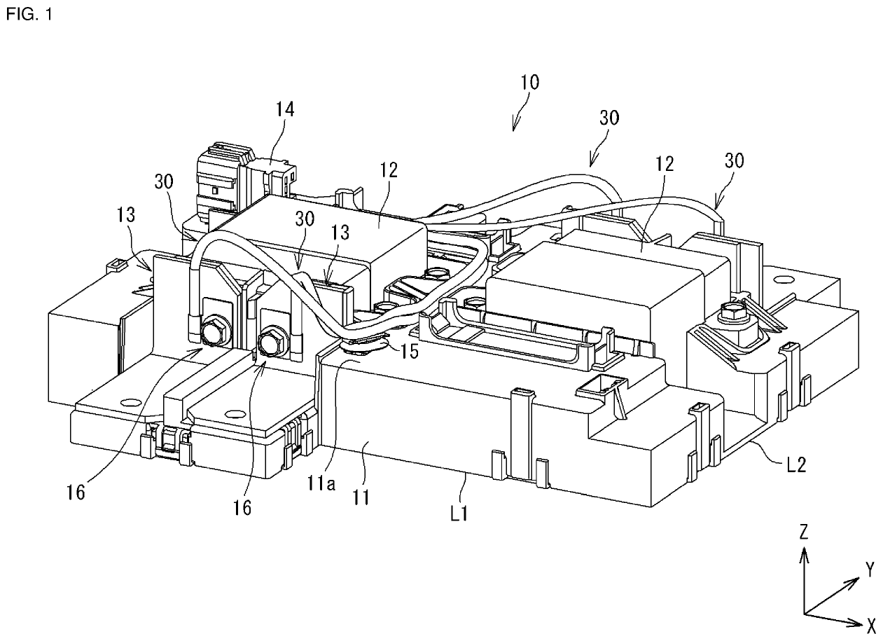

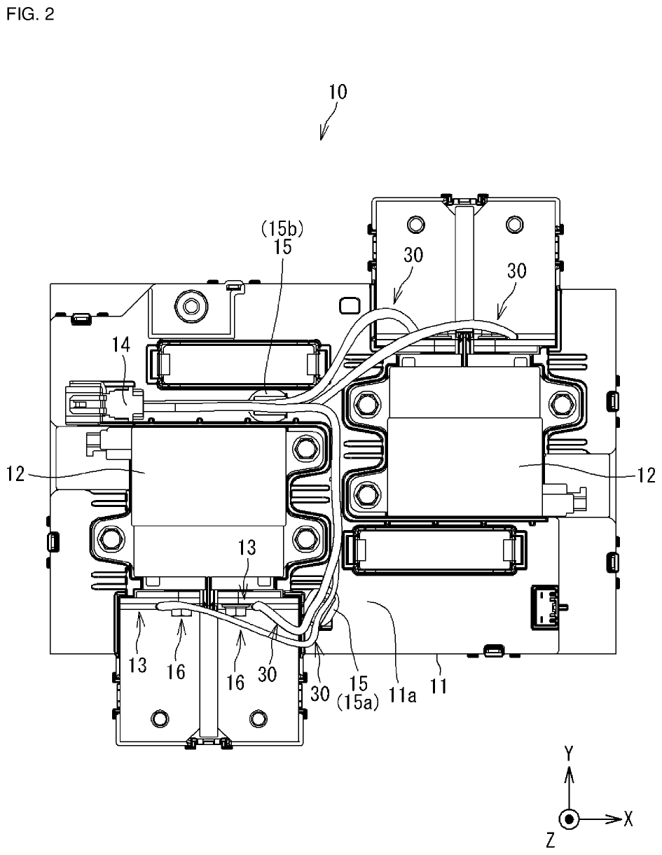

An overall configuration of an electrical connection box 10 according to the embodiment will be described with reference to FIGS. 1 and 2.

FIG. 1 is a perspective view schematically illustrating the electrical connection box 10.

FIG. 2 is a plan view schematically illustrating the electrical connection box 10.

The electrical connection box 10 is a member connected between a battery of an automobile and a plurality of in-vehicle devices, and is also referred to as a junction box (JB). The electrical connection box 10 includes a case 11, at least one relay 12, at least one bus bar 13, a connector 14, at least one clamp 15, at least one connection portion 16, at least one sensor 20, and at least one wire harness 30.

The case 11 has a box shape that is flattened overall, although it includes recesses and protrusions. The flattened direction, that is, the direction in which the thickness is less, is defined as an “up-down direction”. The relay 12 is attached from one side (from above, in FIG. 1) of the case 11. The side on which the relay 12 is attached is defined as the “upper side”. Also, the direction along a long side L1 of the case 11 is defined as a left-right direction, and the direction along a short side L2 of the case 11 is defined as a front-rear direction. XYZ orthogonal coordinates are shown in the diagrams. The Z-direction is a direction from below to above (up-down direction), the Y-direction is a direction from front to back (front-rear direction), and the X-direction is a direction from left to right (left-right direction).

The relay 12 is electrically connected between the battery and in-vehicle devices, and is a component that controls on/off of power supply from the battery to the in-vehicle devices. The relay 12 is a mechanical relay, for example, and accommodates a coil, a spring, and the like therein. The relay 12 is attached to an upper side of the case 11 in a state exposed outside the case 11. In the present embodiment, a plurality of (two, specifically) relays 12 are attached to the case 11, but there is no particular limitation to the number of relays 12 attached to the case 11.

The relay 12 of the present embodiment is a high-voltage relay that can operate at a voltage (e.g., 30V or higher) higher than a normal voltage (e.g., 12 V, 24 V). Therefore, the temperature of the relay 12 is likely to increase to a high temperature due to application of the high-voltage. In the present embodiment, the temperature of the relay 12 is detected by the sensor 20 in order to perform a protection operation when the temperature of the relay 12 exceeds a heat-resistant temperature. A thermistor is used as the sensor 20, for example. Note that the type of the sensor 20 is not limited in particular, as long as the sensor can measure the state of the relay 12. For example, the sensor 20 may also be a sensor that measures the ambient temperature of the relay 12 (e.g., atmospheric temperature around the relay 12, or temperature of the case 11), instead of the temperature of the relay 12 itself. Also, the sensor 20 may also be a sensor that measures the ambient humidity of the relay 12, or a sensor that measures the acceleration applied to the relay 12.

The bus bar 13 is a conductive member whose one end is electrically connected to the relay 12, and whose other end is electrically connected to an in-vehicle device or the battery. When the relay 12 is turned on, a current flows through the bus bar 13.

The wire harness 30 is a bundle of interconnects that are routed outside the case 11. One end of the wire harness 30 is connected to the sensor 20, and the other end thereof is connected to the connector 14. In the present embodiment, two wire harnesses 30 are connected to one relay 12, and four wire harnesses 30 are connected to the connector 14 in total. However, there is no particular limitation to the number of wire harnesses 30.

The connector 14 is a member for electrically connecting the wire harnesses 30 and external interconnects, which are not illustrated. Through the external interconnects, the detection signals of the sensors 20 are transmitted to an apparatus outside the electrical connection box 10. The connector 14 is a so-called external connector to be attached to a case, and is fixed to an outer wall 11a of the case 11, for example.

The clamp 15 is a member for locally fixing the wire harness 30 that extends from the connection portion 16 to the connector 14. As shown in FIG. 2, a plurality of (two in the present embodiment) clamps 15 are provided on the outer wall 11a of the case 11. Hereinafter, a front clamp 15 will be referred to as a “first clamp 15a” as appropriate, and a rear clamp 15 will be referred to as a “second clamp 15b” as appropriate. The wire harness 30 is routed from the connection portion 16 to the connector 14 via the first clamp 15a and the second clamp 15b in the stated order.

The connection portion 16 is a part for attaching the bus bar 13 to the relay 12, and is also a part for attaching the wire harness 30 to the bus bar 13. In the present embodiment, a pair of bus bars 13 and a pair of connection portions 16 are attached to one relay 12.

### Configuration of Bus Bar and Connection Portion

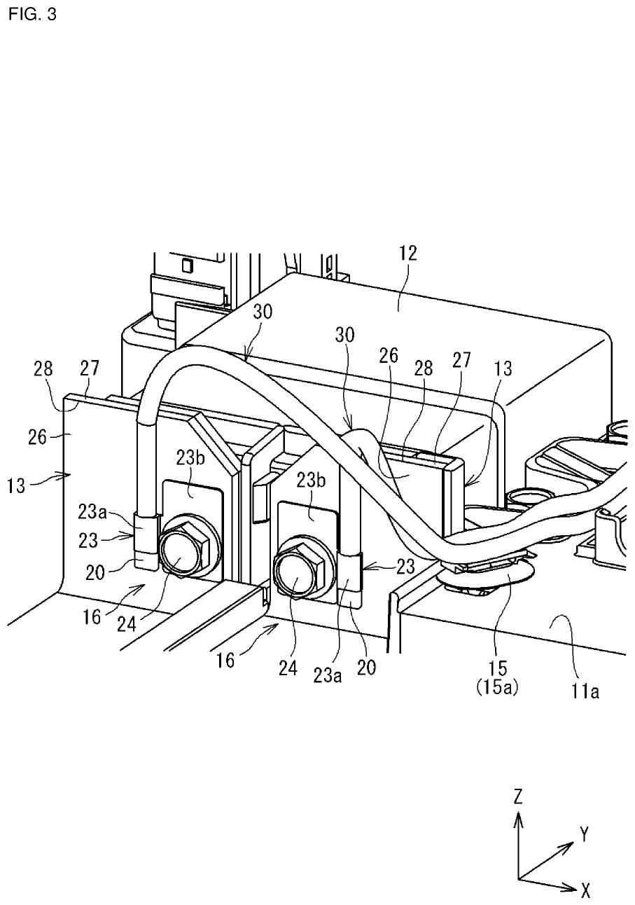

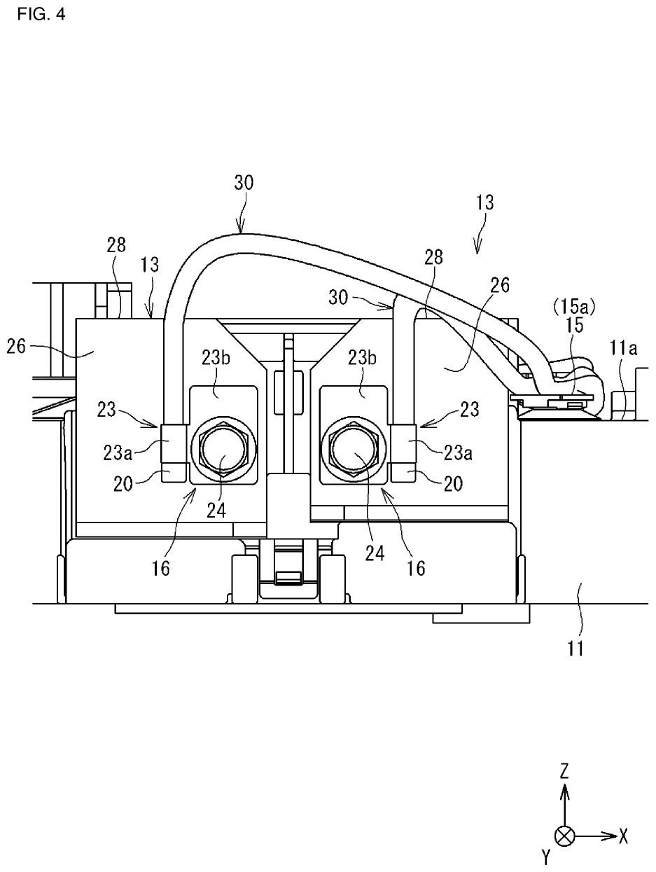

The bus bar 13 and the connection portion 16 of the present embodiment will be described below with reference to FIGS. 3 and 4.

FIG. 3 is an enlarged view of a portion, of the perspective view in FIG. 1, including the bus bars 13 and the connection portions 16.

FIG. 4 is an enlarged view of the portion including the bus bars 13 and the connection portions 16, viewed from the front in the front-rear direction.

Each bus bar 13 includes a front face 26 facing frontward, an upper face 27 facing upward, and corner 28 that is a boundary between the front face 26 and the upper face 27. A through hole for inserting a later-described fastening member 24 is formed in the front face 26.

Each connection portion 16 includes a holding member 23 and a fastening member 24. The holding member 23 is a metal member for holding the sensor 20 and the wire harness 30 on the bus bar 13. The holding member 23 includes a tubular portion 23a into which an end portion of the wire harness 30 on the sensor side is inserted, and a flat plate portion 23b provided with the through hole into which the fastening member 24 is to be inserted. The end portion of the wire harness 30 on the sensor 20 side is held by the tubular portion 23a in a state in which the sensor 20 protrudes downward from the tubular portion 23a.

The fastening member 24 is a bolt, for example. The flat plate portion 23b is located on the front face 26 of the bus bar 13, and the positions of the through hole of the flat plate portion 23b and the through hole of the front face 26 are matched, and in this state, the fastening member 24 is inserted into these through holes and fastened, and as a result, the holding member 23 and the bus bar 13 are fixed to the relay 12.

### Configuration of Wire Harness

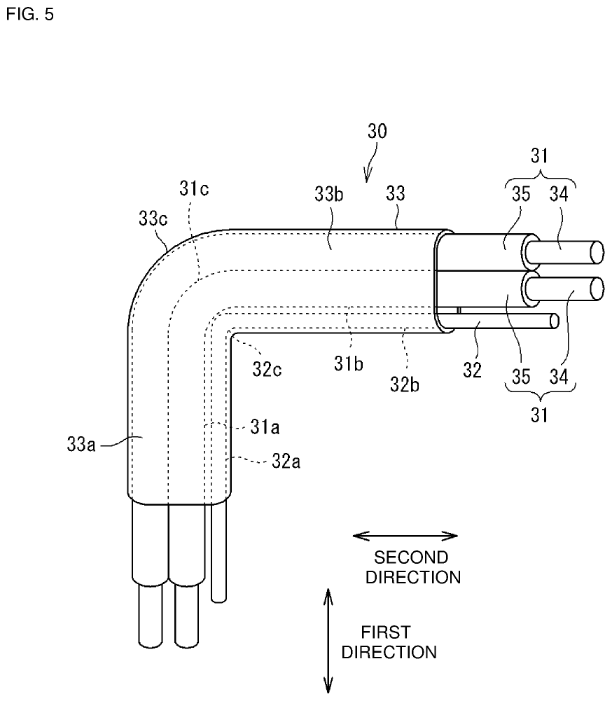

The wire harness 30 of the present embodiment will be described with reference to FIG. 5.

FIG. 5 is a schematic diagram for describing the wire harness 30. The wire harness 30 includes a pair of leads 31 for transmitting a detection signal of the sensor 20, a guide member 32, and a fixing member 33. The leads 31 are to be electrically connected to the sensor 20.

Each lead 31 is a vinyl coated wire including a conductive wire 34 and a vinyl inner tube 35. The conductive wire 34 may be a single wire or may also be a “stranded wire” including a plurality of wires. The inner tube 35 is an insulating covering (sheath) covering the conductive wire 34. The inner tube 35 is provided for insulation between the pair of conductive wires 34 and between the conductive wires 34 and the guide member 32. The pair of leads 31 may extend in parallel adjacent to each other, as shown in FIG. 5, or may also extend in a twisted state.

In order to facilitate the wiring work, the leads 31 are flexible so as to be bent easily by a human hand. If the leads 31 are flexible, the wiring work is facilitated, but on the other hand, after the leads 31 have been routed in the case 11, the flexibility is also a cause for inducing damage to the leads 31. For example, when the case 11 jolts due to vibration accompanying traveling of a vehicle, the leads 31 also jolt while undergoing bending, and therefore there is a risk that the leads 31 are damaged by scraping against parts outside the case 11 (e.g., the corner 28 of the bus bar 13).

Therefore, in the present embodiment, the guide member 32 is provided to guide the leads 31, and the position of the leads 31 is restricted. With this, the risk of the leads 31 being damaged is reduced. The guide member 32 is a member provided along the leads 31 for guiding the extending direction of the leads 31.

The guide member 32 is, specifically, a wire whose rigidity in the bending direction is larger than the lead 31. The bending direction is a direction intersecting the extending direction of the guide member 32 (or, lead 31). A larger force is required to bend the guide member 32 than in the case of bending the lead 31. The guide member 32 may be bent by a machine or the like in advance in a direction in which the lead 31 is guided, or may also be bent in a direction in which the lead 31 is guided by a worker using a tool or by hand when attaching the wire harness 30. As shown in FIG. 5, the guide member 32 includes a first part 32a extending in a first direction (up-down direction in FIG. 5), a second part 32b extending in a second direction (left-right direction in FIG. 5) intersecting the first direction, and a curved portion 32c that is bent from the first direction to the second direction. The intersecting angle between the first direction and the second direction is 90 degrees in FIG. 3, but there is no limitation to this. Also, the radius of curvature of the curved portion 32c is not specifically limited.

Note that the guide member 32 may also be a resin bar whose rigidity in the bending direction is larger than the lead 31. In this case, the guide member 32 is formed, in advance, so as to extend in a guiding direction of the lead 31. The resin material of the guide member 32 is not specifically limited, and may be a general-purpose plastic such as polyethylene or polypropylene, may also be an engineering plastic such as polycarbonate or polybutylene terephthalate, or may also be a thermosetting resin such as phenol resin.

The fixing member 33 is provided along the guide member 32, and is a member for fixing the leads 31 to the guide member 32. Specifically, the fixing member 33 is a resin tube (hereinafter, may also be referred to as an “outer tube 33”) that houses a pair of leads 31 and the guide member 32 therein. The outer tube 33 has a smaller rigidity in the bending direction than the guide member 32, and is easily bent. Also, the inner peripheral surface of the outer tube 33 is in contact with the leads 31 and the guide member 32.

Therefore, the extending direction of the outer tube 33 is guided by the guide member 32. That is, an outer first part 33a, of the outer tube 33, that covers the first part 32a extends in the first direction, and an outer second part 33b, of the outer tube 33, that covers the second part 32b extends in the second direction. Also, an outer curved portion 33c, of the outer tube 33, that covers the curved portion 32c bends from the first direction to the second direction, similarly to the guide member 32.

Also, the leads 31 are guided in the extending direction of the outer tube 33 by coming into contact with the inner peripheral surface of the outer tube 33. That is, the guide member 32 can indirectly guide the leads 31 via the outer tube 33. As a result, lead first parts 31a, of the leads 31, that are covered by the outer first part 33a extend in the first direction. Also, lead second parts 31b, of the leads 31, that are covered by the outer second part 33b extend in the second direction. Also, lead curved portions 31c, of the leads 31, that are covered by the outer curved portion 33c bend from the first direction to the second direction, similarly to the guide member 32 and the outer tube 33.

As described above, the leads 31 are fixed in a predetermined orientation by the guide member 32 and the fixing member 33. The lead first part 31a and lead second part 31b are restricted to extend straight, and the lead curved portion 31c is restricted to bend with a predetermined radius of curvature. That is, the position of the leads 31 is restricted by the guide member 32 and the fixing member 33. As a result, the position of the wire harness 30 including the leads 31 is also restricted.

Specifically, the positions of the wire harnesses 30 are restricted such that the wire harnesses 30 will not unintentionally come into contact with parts outside the case 11. For example, as shown in FIG. 3, the wire harnesses 30 are fixed to positions such that the wire harnesses 30 will not come into contact with the bus bar 13 and the case 11, in a section from the connection portion 16 to the first clamp 15a. Accordingly, the risk that the leads 31 are damaged by scraping against parts (e.g., corner 28) outside the case 11 can be reduced.

Here, if a plate for guiding the lead 31 is provided in the outer wall 11a of the case 11, for example, a bolt or the like for fixing the plate to the outer wall 11a is separately needed, and therefore there is a problem in that the number of components increases, and the size of the electrical connection box 10 increases. In contrast, the guide member 32 of the present embodiment is housed in the outer tube 33 along with the leads 31. Therefore, the configuration of the electrical connection box 10 can be simplified, compared with the case where a plate for guiding the lead 31 is provided in the outer wall 11a.

The guide member 32 and fixing member 33 may be provided over the entire length of the leads 31, or may also be provided in portions of the leads 31 that may be damaged by scraping. In the present embodiment, the portion of the leads 31 that is highly likely to be damaged is a portion adjacent to the corner 28 of the bus bar 13. Therefore, the guide member 32 and fixing member 33 may be provided only in a section from the connection portion 16 to the first clamp 15a, which includes a portion adjacent to the corner 28 of the bus bar 13, and may not be provided in a section from the first clamp 15a to the connector 14, for example.

As described above, as a result of providing the guide member 32 and fixing member 33 partially relative to the entire length of the leads 31, the risk that the leads 31 will be damaged can be reduced while maintaining the ability to easily perform wiring work of the leads 31 (wire harness 30).

As described above, the electrical connection box 10 according to the present embodiment includes the case 11, the relay 12 attached to the case 11 in a state exposed outside the case 11, and the wire harness 30 that is connected to the sensor 20 that measures the state of the relay 12, and is routed outside the case 11. The wire harness 30 includes the leads 31 electrically connected to the sensor 20, and the guide member 32 that is provided along the leads 31 and guides the extending direction of the leads 31.

### Modifications

Modifications of the embodiment will be described below. In the following modifications, the constituent elements that are the same as those of the embodiment are given the same reference numerals, and the description thereof will be omitted.

### Modification of Fixing Member

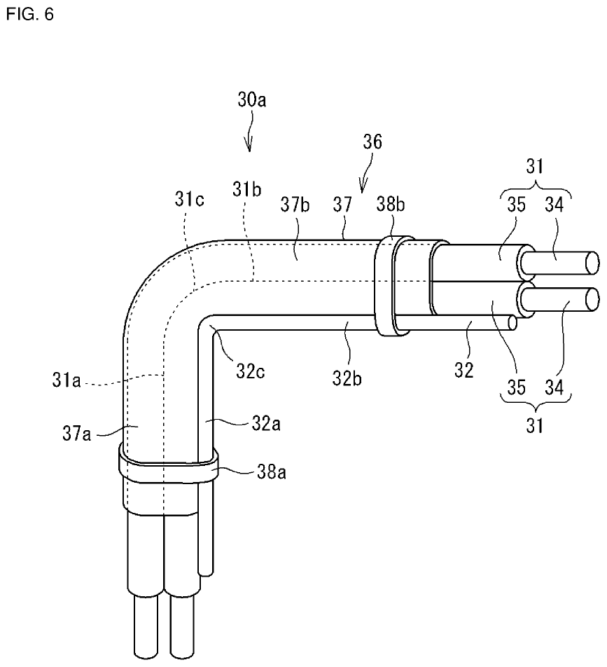

FIG. 6 is a schematic diagram for describing a wire harness 30a according to a modification of the present embodiment. The fixing member 33 of the embodiment is the outer tube 33 that houses the pair of leads 31 and the guide member 32. However, the fixing member need only be a member for fixing the leads 31 so as to extend along the guide member 32, and is not limited to the outer tube 33.

The wire harness 30a according to the modification includes the pair of leads 31, the guide member 32, and a fixing member 36. The fixing member 36 includes a resin outer tube 37 housing the pair of leads 31, and a plurality of binding bands 38a and 38b for fixing the guide member 32 to an outer peripheral surface of the outer tube 37. The outer tube 37 has a smaller rigidity in the bending direction than the guide member 32, and is easily bent. Also, the inner peripheral surface of the outer tube 37 is in contact with the leads 31.

A binding band 38a fixes the first part 32a of the guide member 32 to an outer first part 37a of the outer tube 37 that covers the lead first parts 31a. A binding band 38b fixes the second part 32b of the guide member 32 to an outer second part 37b of the outer tube 37 that covers the lead second parts 31b. That is, the plurality of binding bands 38a and 38b are provided so as to sandwich the curved portion 32c of the guide member 32. With this, the lead first parts 31a and the outer first part 37a are guided in the first direction, and the lead second parts 31b and the outer second part 37b are guided in the second direction.

Note that the fixing member 36 may include only the plurality of binding bands 38a and 38b while omitting the outer tube 37. The outer tube 37 mainly has a function of bundling the pair of leads 31, and a function of providing insulation between the leads 31 and the guide member 32, but if these functions are not needed (e.g., when sufficiently insulated from the guide member 32 by the inner tube 35), the outer tube 37 may not be provided.

### Modification of Guide Member

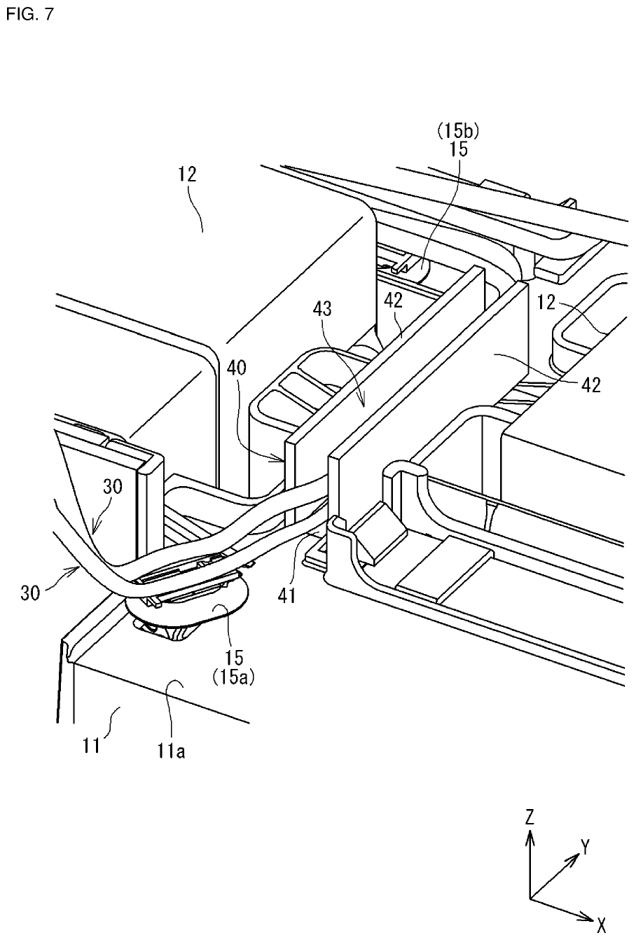

FIG. 7 is a schematic diagram for describing an electrical connection box according to a modification of the embodiment. The electrical connection box 10 according to the modification further includes a second guide member 40 (guide-rail) in addition to the configuration of the embodiment.

The second guide member 40 is provided, on the outer wall 11a of the case 11, between the plurality of relays 12 shown in FIG. 1 in the left-right direction, and guides the wire harnesses 30 in a section from the first clamp 15a to the second clamp 15b. The second guide member 40 is a resin member, and includes a bottom plate 41 extending in the front-rear direction, and a pair of side walls 42 that extend upward from left and right ends of the bottom plate 41. The pair of side walls 42 are integrally formed with the bottom plate 41.

The wire harnesses 30 are inserted in a space 43 surrounded by the bottom plate 41 and the pair of side walls 42. The position of the wire harnesses 30 in the left-right direction is restricted by the pair of side walls 42. Accordingly, the wire harnesses 30 can be prevented from scraping against unintended portions of the outer wall 11a of the case 11, and the risk of the wire harnesses 30 being damaged can be reduced.

Note that the position at which the second guide member 40 is provided is not limited to the position shown in FIG. 7. For example, the second guide member may be provided behind the left relay in FIG. 1 along the left-right direction, and guide the wire harnesses 30 in a section from the second clamp 15b to the connector 14

### SUPPLEMENTARY NOTE

Note that, with respect to the embodiment and various modifications, at least some of them may be combined as necessary. Also, the embodiment disclosed herein is illustrative in all aspects and should not be considered restrictive. The scope of the present disclosure is indicated by the scope of claims, and is intended to include all modifications within the meaning and scope equivalent to the scope of claims.

1. An electrical connection box comprising:
a case;
a relay attached to the case in a state exposed outside the case; and
a wire harness that is configured to be connected to a sensor that measures a state of the relay, and is provided outside of the case,
wherein the wire harness includes:
a lead to be electrically connected to the sensor; and
a guide member provided along the lead to guide an extending direction of the lead.

2. The electrical connection box according to claim 1, wherein the guide member is a wire whose rigidity in a bending direction is larger than the lead.

3. The electrical connection box according to claim 1, wherein the guide member is a resin bar formed so as to extend in a direction in which the lead is to be guided.

4. The electrical connection box according to claim 1, wherein the wire harness further includes a resin tube housing the lead and the guide member.

5. The electrical connection box according to claim 2, wherein the wire harness further includes a resin tube housing the lead and the guide member.

4. The electrical connection box according to claim 3, wherein the wire harness further includes a resin tube housing the lead and the guide member.
